(19) United States
(12) Patent Application Publication
(10) Pub. No.: US 2013/0233987 A1
(43) Pub. Date: Sep. 12, 2013

(54) FASTENING DEVICE FOR HARD DISK DRIVE

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/463,831

(22) Filed: May 4, 2012

(30) Foreign Application Priority Data
Mar. 8, 2012 (CN) 201210059197.7

(51) Int. Cl. H05K 7/00

(52) U.S. Cl. 248/221.11

(57) ABSTRACT

A fastening device for a hard disk drive (HDD) includes two fastening members and a bottom plate. Each fastening member includes a sidewall, and a top wall and a bottom wall perpendicularly extending from opposite sides of the sidewall. The top walls are fastened to a bottom of the HDD. An engaging hole is defined in each bottom wall. The engaging hole includes a small first hole and a large second hole communicating with the first hole. One of the fastening members further includes a locking tab. Two protrusions protrude from the bottom plate. The HDD is operable to slide to allow the protrusions to enter and engage with the corresponding first holes from the second holes. A fastener extends through the locking tab and then engages in the bottom plate to fix the HDD in place.

### BACKGROUND

1. Technical Field

The present disclosure relates to a device for fastening a hard disk drive (HDD).

2. Description of Related Art

Many HDDs are screwed to brackets in computers, so the HDDs are rigidly connected to chassis of the computers, which means any vibrations or shocks to the chassis are easily transferred to the HDDs. When an HDD is operating at a high speed, such vibrations may harm the HDD.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fastening device together with a hard disk drive (HDD), wherein the fastening device includes a first fastening member and a second fastening member.

FIG. 2 is an inverted view of FIG. 1.

FIG. 3 is an enlarged view of the first fastening member of FIG. 2.

FIG. 4 is an enlarged view of the second fastening member of FIG. 2.

FIG. 5 is an enlarged view of a circled portion V of FIG. 1.

FIG. 6 is an assembled view of the HDD, the first fastening member and the second fastening member of FIG. 2.

FIG. 7 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

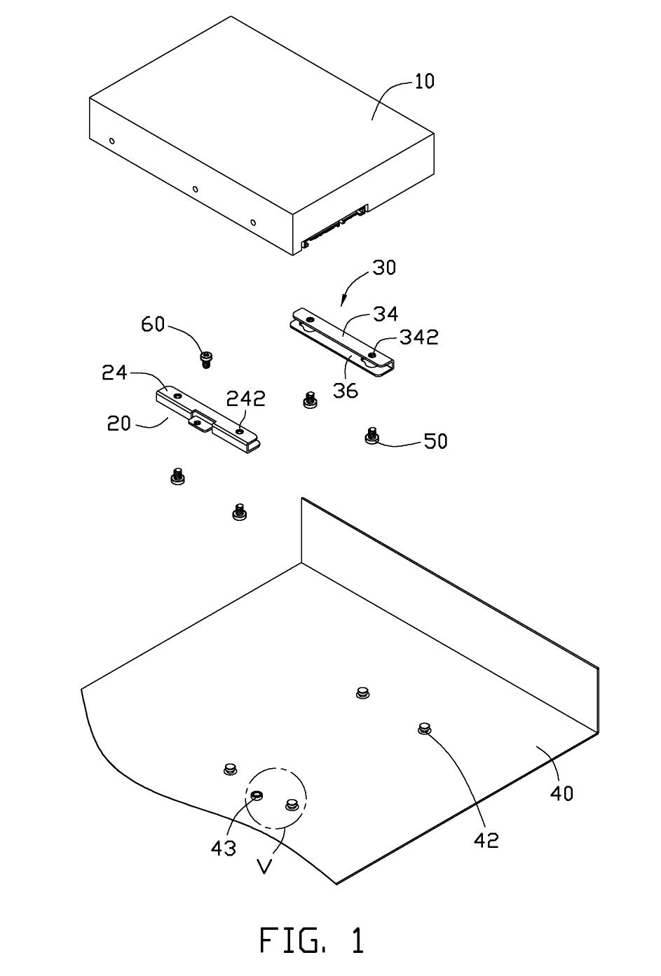

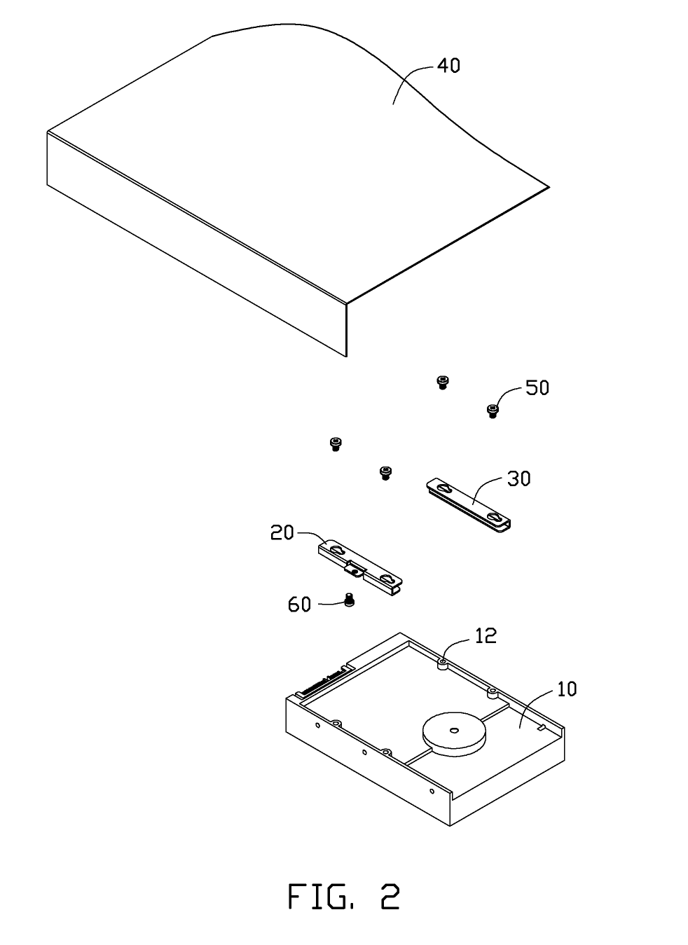

FIGS. 1 and 2 show an exemplary embodiment of a fastening device for a hard disk drive (HDD) 10. Four mounting holes 12 are defined in a bottom wall of the HDD 10. The fastening device includes a first fastening member 20, a second fastening member 30 and a bottom plate 40.

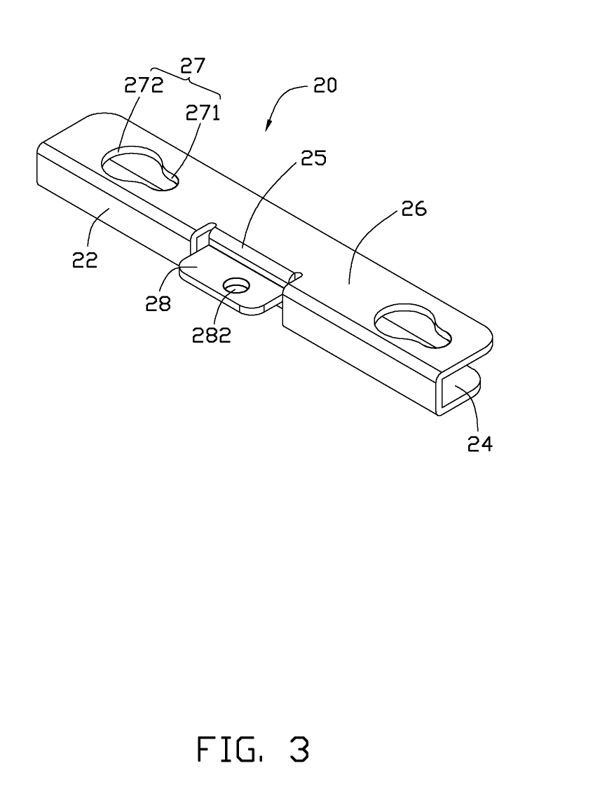

FIGS. 1 and 3 show the substantially U-shaped first fastening member 20. The first fastening member 20 includes a long sidewall 22, and a top wall 24 and a bottom wall 26 perpendicularly extending from opposite sides of the sidewall 22. Two through holes 242 are defined in opposite ends of the top wall 24. Two engaging holes 27 are defined in opposite ends of the bottom wall 26, each with a shape of an old-fashioned keyhole. Each engaging hole 27 includes a small first hole 271 and a large second hole 272 communicating with the first hole 271. An opening 25 is defined in a middle of the sidewall 22, extending through the top wall 24 and bottom wall 26. An L-shaped locking tab 28 extends from the bottom wall 26 adjoining the opening 25. The locking tab 28 extends up and then extends out of the sidewall 22. A through hole 282 is defined in a top of the locking tab 28.

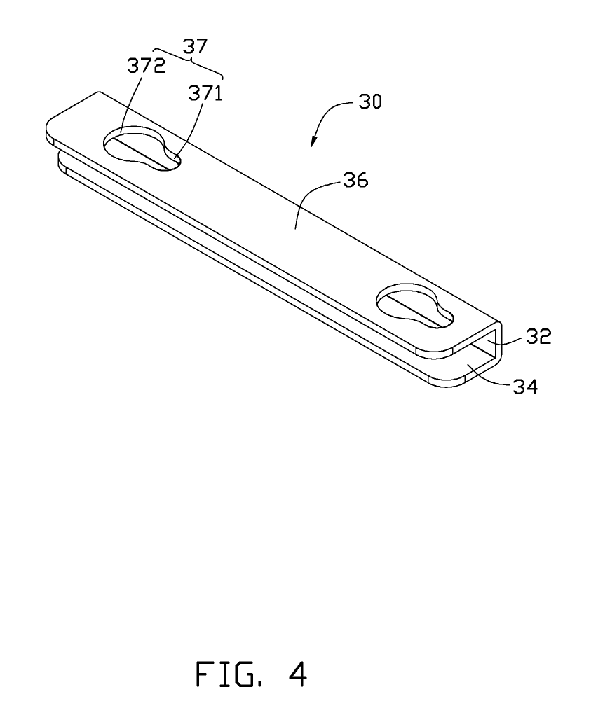

FIGS. 1 and 4 show the U-shaped second fastening member 30 which is similar to the first fastening member 20. The second fastening member 30 includes a long sidewall 32, and a top wall 34 and a bottom wall 36 perpendicularly extending from opposite sides of the sidewall 32. Two through holes 342 are defined in opposite ends of the top wall 34. Two engaging holes 37 are defined in opposite ends of the bottom wall 36. Each engaging hole 37 includes a small first hole 371 and a large second hole 372 communicating with the first hole 371. Except for the opening 25 and the locking tab 28, the second fastening member 30 is a mirror image of the first fastening member 20.

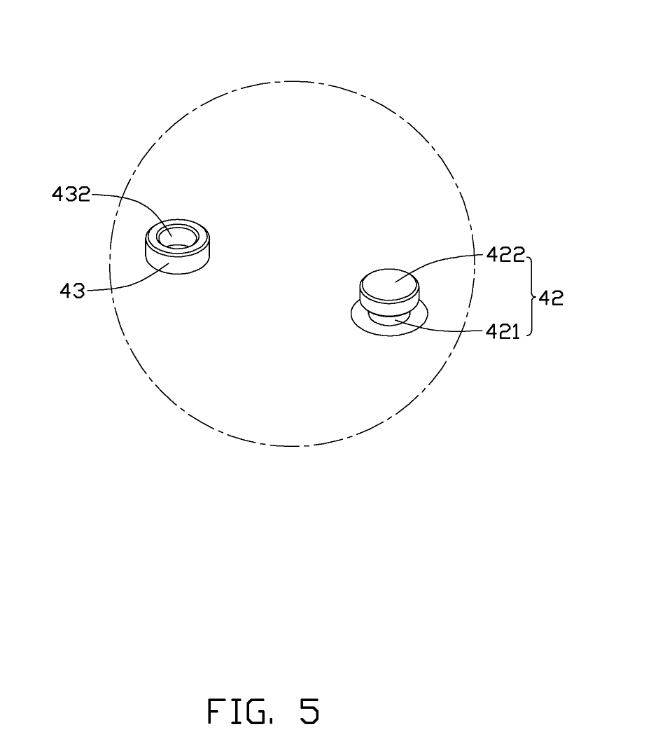

FIGS. 1 and 5 show four protrusions 42 protruding up from the bottom plate 40. The protrusions 42 are arranged as a rectangle. Each protrusion 42 includes a small neck 421 extending up from the bottom plate 40 and a large head 422 on a top of the neck 421. A locking protrusion 43 protrudes up from the bottom plate 40, beside the protrusions 42. A locking hole 432 is defined in a top of the locking protrusion 43.

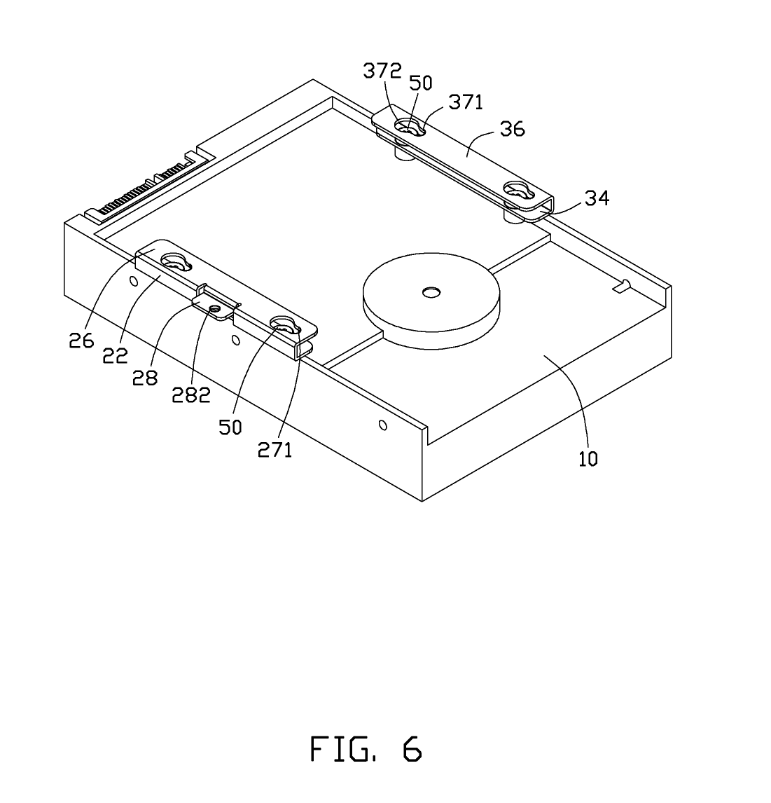

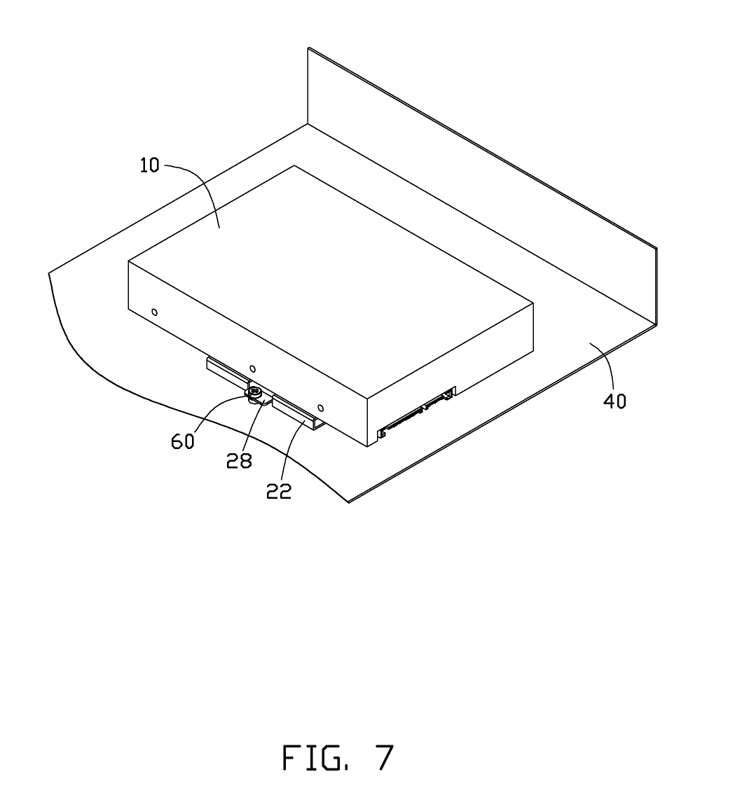

FIGS. 6 and 7 show in assembly, the top walls 24 and 34 abut against the bottom wall of the HDD 10, and the through holes 242 and 342 align with the corresponding mounting holes 12. Four screws 50 extend through the corresponding through holes 242 and 342, and engage in the corresponding mounting holes 12, to fasten the first fastening member 20 and the second fastening member 30 to the HDD 10. The first fastening member 20 and second fastening member 30 are placed above the bottom plate 40, and the second holes 272 and 372 are aligned with the corresponding protrusions 42. The first fastening member 20 and the second fastening member 30 are manipulated down to abut against the bottom plate 40, to gather the protrusions 42 into the second holes 272 and 372. In the manner of a slot lock, the HDD 10, the first fastening member 20 and the second fastening member 30 are moved to allow the necks 421 to engage in the corresponding first holes 271 and 371. The heads 422 abut against the corresponding bottom wall 26 and 36. The through hole 282 of the locking tab 28 aligns with the locking hole 432 of the locking protrusion 43. A fastener 60, such as a screw, extends through the through hole 282 and engages in the locking hole 432, to fasten the HDD 10 to the bottom plate 40.

The HDD 10 is fastened to the bottom plate 40 by the U-shaped first fastening member 20 and second fastening member 30, a certain distance above the bottom plate 40. When the first fastening member 20 and second fastening member 30 are subjected to vibrations or shocks, the first fastening member 20 and second fastening member 30 can deform to absorb at least part of vibration energy.

In other embodiments, the opening 25 is omitted, and the locking tab 28 extends out from an outer side of the sidewall 22, parallel to the top wall 24.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A fastening device for a hard disk drive (HDD), comprising:
two fastening members each comprising a sidewall, and a top wall and a bottom wall perpendicularly extending from opposite sides of the sidewall, the top walls fastened to a bottom of the HDD, an engaging hole defined in each bottom wall, the engaging hole comprising a small first hole and a large second hole communicating with the first hole, one of the fastening members further comprising a locking tab; and
a bottom plate, and two protrusions protruding from the bottom plate, wherein the HDD is operable to slide to allow the protrusions to respectively enter and then engage with the first holes from the corresponding second holes, a fastener is operable to extend through the locking tab and then engage in the bottom plate.

2. The fastening device of claim 1, wherein each protrusion comprises a small neck extending up from the bottom plate and a large head on a top of the neck, the necks engage in the corresponding first holes, the heads abut against top surfaces of the corresponding bottom walls.

3. The fastening device of claim 1, wherein the sidewall of the fastening member with the locking tab defines an opening extending through the corresponding bottom wall, the locking tab extends up from the bottom wall adjoining the opening and then extends out of the corresponding sidewall.

4. The fastening device of claim 1, wherein the locking tab extends out from an outer side of the corresponding sidewall, parallel to the corresponding top wall.

5. The fastening device of claim 1, wherein a through hole is defined in the locking tab, a locking protrusion protrudes from the bottom plate, a locking hole is defined in the locking protrusion, the fastener extends through the through hole and then engages in the locking hole.
